(19) United States
(12) Patent Application Publication
(10) Pub. No.: US 2002/0044074 A1
(43) Pub. Date: Apr. 18, 2002

(54) Relational differentiation encoding

(76) Inventor: Peter St. George, West Palm Beach, FL (US)

Correspondence Address: R. WHITNEY WINSTON, Fish & Richardson P.C., 601 Thirteenth Street N.W,, Washington, DC, 20005, US

(21) Appl. No.: 09/939,762

(22) Filed: Aug. 28, 2001

Related U.S. Application Data
(60) Provisional application No. 60/228,620, filed on Aug. 28, 2000.

(51) Int. Cl. H03M 7/30

(52) U.S. Cl. 341/76

(57) ABSTRACT

A system and method for encoding data is provided. A relational differentiation encoding module is used to encode a target value by constructing a set of values including the target, and then by differentiating the target from the constructed set of values. The constructed set of values may be defined by calculating the senior most bit (SMB) and the so many on/off bits (SMOB) of the target value. Armatures may be calculated to further differentiate the target value.

### RELATIONAL DIFFERENTIATION ENCODING

This application claims priority from U.S. Provisional Application No. 60/228,620, titled “Relational Differentiation Encoding for a Data Transmission”, and filed Aug. 28, 2000, the contents of which are hereby incorporated by reference.

### TECHNICAL FIELD

This invention relates to data encoding, and more particularly to providing a compact data representation using relational differentiation encoding.

### BACKGROUND

Computers commonly use a binary data encoding system to store, process, and transmit data. For example, the number “4254” may be encoded as the binary string “1000010011110”. Some coding systems, such as Huffman encoding, represent binary data in a manner that takes advantage of repeating information to provide a compact data representation. If a long bit string, such as “101101001101011101,” repeats many times within a bit string, then all instances of the long bit string may be replaced by a much shorter representation of that bit string. Such run-length encoding techniques may be employed to create a more compact data representation.

Compression and/or data representation techniques may be used to significantly reduce the size of a bit string, with the resulting compact representation usually resembling a random string of bits with little redundancy or repeating patterns. It is widely believed that the resulting random bit string cannot be further compressed. However, just as it is possible to encode a number in decimal, hexadecimal, and binary data representations, it is possible to encode a random string of bits with a coding scheme more compact data representation.

Many modern computer systems are limited by the amount of data that can be stored or transmitted. For example, today's modems have reached a bottleneck due to physical and legal limits of modem technology over copper lines. More compact data representations could alter the bandwidth constraints, permitting increased throughput and density, perhaps fundamentally altering the bottlenecks of modern computer systems.

### SUMMARY

In one general aspect, a method of encoding a target value for storage and/or transmission in a computer system is described. The method includes constructing a set of values that includes the target value, and differentiating the target value from the constructed set of values. A constructed set descriptor describes the constructed set and a differentiation descriptor identifies the target within the constructed set. The target then can be represented using the constructed set descriptor and the differentiation descriptor.

In some implementations, the set of values including the target value is constructed by computing the senior most bit (SMB) of the target value and/or the so many on/off bits (SMOB) of the target value. The SMB may be defined as the position of the most senior bit of the bit string to be encoded. The SMOB may be defined as the number of on or off bits in the bit string.

The constructed set of values may be formed by creating a combinatorial ordered set. For example, a combinatorial ordered set may be defined by the SMB of the target value and the SMOB of the target value.

In some implementations, differentiating the target value includes determining the position of the target value within the constructed set. For example, the target value may be differentiated by computing one or more armatures, with each armature representing the position of the target value within the constructed set. The constructed set includes a first element and a last element. Differentiating the target value may include computing a first armature representing the position of the target value relative to the first element of the constructed set, and computing a second armature representing the position of the target value relative to the last element of the constructed set. The target value can then be differentiated using a description of the two armatures.

Differentiation of the target value may be further refined by constructing a set of good candidates from the constructed set of values by calculating one or more characteristics for each armature, and representing the set of good candidates using the armature characteristics. For example, the set of good candidates may be defined by calculating the SMB and the SMOB for each armature.

The set of good candidates may be further refined by constructing a set of exact matches from the set of good candidates. One way to construct a set of exact matches includes calculating a main difference pair for the target, and characterizing the set of exact matches by the main difference pair. The target value may be fully differentiated by determining the ordinal position of the target within the set of exact matches.

The target value may be represented using the following values: the SMB of the target, the SMOB of the target, the SMB of each of the one or more armatures, the SMOB of each of the one or more armatures, the main difference pair, and the ordinal position of the target within the set of exact matches.

The details of one or more implementations are set forth in the accompanying drawings and the description below. Other features and advantages will be apparent from the description and drawings, and from the claims.

### DESCRIPTION OF DRAWINGS

FIG. 1A is a block diagram of a relational differentiation encoding system.

FIG. 1B is a diagram of a computer system using relational differentiation encoding to encode data for transmission and/or storage.

FIG. 2 is flow chart of the encoding process in a relational differentiation encoding system.

FIG. 3 is a diagram illustrating the bit characteristics of active candidates in a relational differentiation encoding system.

FIG. 4 is a diagram illustrating the calculation of the armatures in a relational differentiation encoding system.

FIG. 5 is a flow chart of the decoding process in a relational differentiation encoding system.

### DETAILED DESCRIPTION

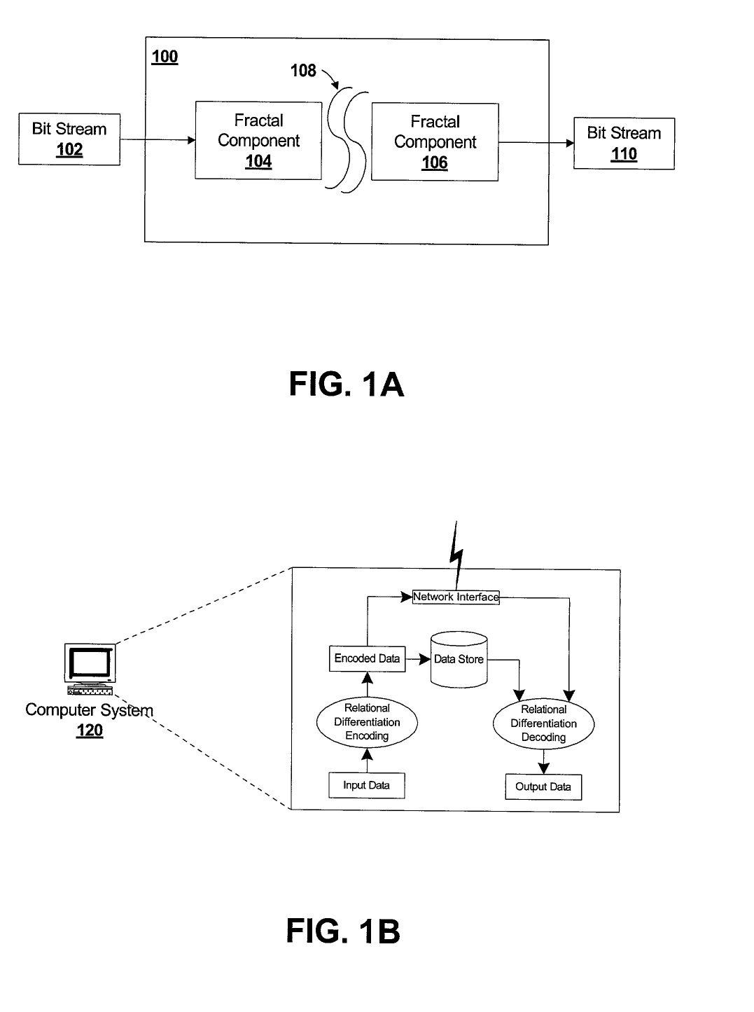

Relational differentiation encoding is a technique that may be used to encode a bit string in a compact data representation. Referring to FIG. 1A, a relational differentiation encoding module 100 receives a bit string 102 as input. The bit string 102 will typically be a binary bit string representing data or information to be transmitted across a communications medium or stored in a data storage medium. For example, bit string 102 may represent data to be transmitted across the Internet, an intranet, a telephone line, a satellite, a local area network, a wide area network, a wireless network, and/or an optical network. Additionally, bit string 102 may represent data to be stored in a memory module, such as a random access memory (RAM), a static RAM (SRAM), a cache memory, or a scratchpad memory; or in a storage module, such as a hard drive, a compact disc, an optical platter, and/or a magnetic tape. The bit string may represent any information including video and audio data.

The relational differentiation encoding module 100 encodes bit string 102 into two fractal components 104 and 106 over a medium 108 to produce a new bit string 110. The original bit string 102 may be reconstituted from the encoded bit string 110 without any loss by reversing the encoding process.

Referring to FIG. 1B, relational differential encoding may be implemented in a computer system 120. A relational differential encoding module 100 receives input data 125, encodes the data into a compact representation 130, and either stores the data in a data store 135 or transmits the data through a network interface 140. The relational differential encoding module may be used with any data within the computer system. FIG. 1B also shows a relational differentiation decoding process 145 whereby encoded data from the data store 135 or the network interface 140 may be decoded into output data 150. The data 150 output from the decoding process is the same as the original data 125 input to the relational differentiation encoding process.

Relational differentiation encoding represents a target value by constructing a set of values containing the target value in a compact form and then by differentiating the target from the other values in the constructed set. For example, one method of using relational differentiation encoding is to determine whether the target value is odd or even. A single bit can be used, with a value of “1” representing odd and a value of “0” representing even. Determining whether the target is odd or even constructs a set of values within which the target lies.

Next, the target must be differentiated from the other values within the constructed set. One way to differentiate the target is to simply count the ordinal position of the target within the constructed set. For example, if a target of 7 is chosen, then the set of odd values is constructed including the following values: 1, 3, 5, 7, . . . . The target is the 4th value in the series. Therefore, the target may be represented as “1” because it is odd and “4” because it is the fourth ordinal value in the series. In this example, the data representation is not compact. In fact, the exact same number of bits is used to represent the target in binary as in the encoded representation. It may be desirable to decrease the number of bits used to represent the ordinal position of the target within the constructed series. Various data representation techniques further refining relational differentiation encoding are described below.

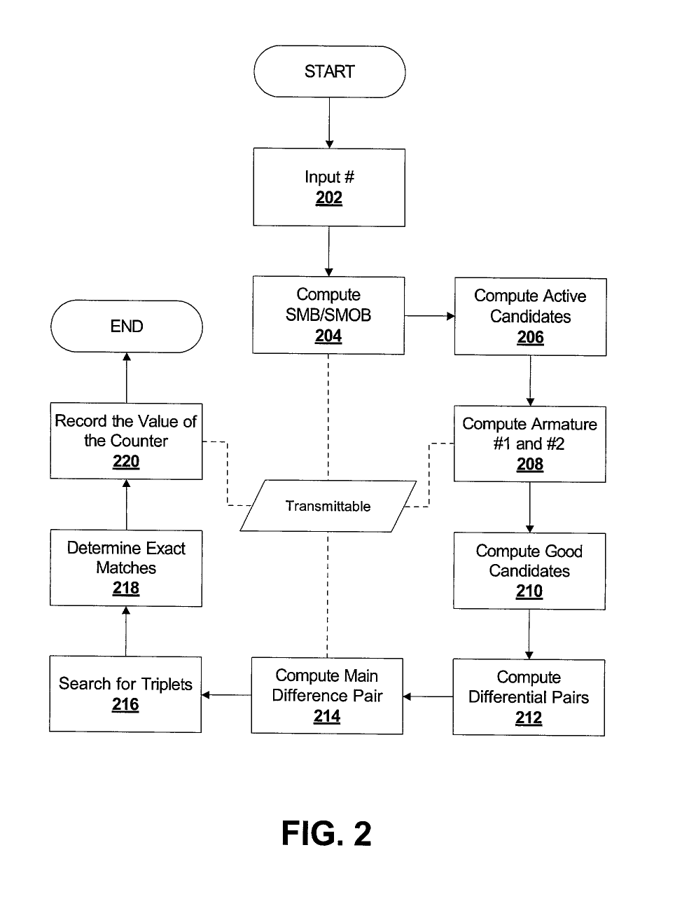

Referring to FIG. 2, a relational differentiation encoding module performs a data encoding process that generates a compact representation of input data. This process is typically performed either by a programmed digital computer, dedicated circuitry, or a combination of the two. Relational differentiation encoding begins by receiving an input (step 202). This input, T, is the target designating the number to be encoded and then later recovered. The target T is encoded so that a reduced number of bits are needed for transmission and storage. The target number can be reconstituted from the bits transmitted or stored.

After the target T is received, the system computes one or more characteristics of the target to create an ordinal series. For example, the system may compute the senior most bit (SMB) and the so many on bits (SMOB) for the target (step 204) to create a combinatorial ordinal series of values. The SMB is the position of the senior most on bit of the bit string to be encoded. For example, an 8-bit binary bit string having a 1 in the high-order position would have an SMB equal to 8. An 1000-bit binary number having a one in the senior most (high-order) position would have an SMB equal to 1000. In the descriptions that follow, SMB is sometimes abbreviated with the capital letter N.

The SMOB is the number of on or 1 bits in a binary stream having a given SMB. Thus, an 8-bit number having an SMB of 8 and four on bits has an SMOB of 4. Similarly, a 1000-bit binary number having an SMB of 1000 and 365 on bits has an SMOB of 365. In the description that follows, SMOB is sometimes abbreviated with the capital letter R. It should be noted that SMOB may also be applied to the number of off bits. In the event that the off bits are used, the results are the same, except that the expressions obtained are complimentary.

The SMB and SMOB together form a SMB/SMOB record (hereinafter, “SSR record”). Using the SSR record, the next step is to identify a subset of the possible values of T that have the same SSR record as T (step 206). These values are called active candidates. Consideration only of values that have the same SSR record may significantly reduce the space of possible values and thus reduce the number of bits needed to represent the target T. However, much of the time, the ordinal position of the target T within the constructed combinatorial series defined by the SSR record is still large.

For example, consider a target T equal to 34 which may be represented in binary as “100010”. The SMB of T is 6 because there are 6 binary bits used to represent T. The SMOB of T is 2 because T has 2 on bits. The active candidates are those numbers that have the same SSR record as T, i.e., those having 6 bits with 2 on bits. There are 5 active candidates having the same SSR record as shown below in Table 1. Because the most significant bit must be 1, the number of active candidates may be computed by calculating the number of combinations of the remaining SMB−1 bits given SMOB−1 on bits. This may be computed using elementary combinatorics. The value ^{N-1}C_{R-1} determines the number of active candidates and may be computed as follows:

$${}^{N - 1} {C}_{R - 1} = \frac{( N - 1 ) !}{( N - R ) ! ( R - 1 ) !} .$$

For an SMB of 6 and a SMOB of 2, the number of active candidates is

$${}^{6 - 1} {C}_{2 - 1} = \frac{( 6 - 1 ) !}{( 6 - 2 ) ! ( 2 - 1 ) !} = \frac{5 !}{4 ! 1 !} = 5.$$

TABLE 1

| T (Binary) | T (Decimal) |
|---|---|
| 100001 | 33 |
| 100010 | 34 |
| 100100 | 36 |
| 101000 | 40 |
| 110000 | 48 |

The number of active candidates is often a very large number. The data representation must be able to identify a target from the ordinal set of all active candidates. For example, the system could simply identify a count representing the order in which the target T appears within the series. For a target of 34, T is second within the ordinal series of active candidates. The size of the set of active candidates may be very large, so it is often desirable to further reduce the information needed to identify a particular target T.

In one implementation, the active candidate space is reduced by computing two values called armatures (step 208). In this example, the armatures represent the first fractal component 104 and the second fractal component 106. The first armature is the number of active candidates from the smallest active candidate to the target in consideration. The second armature is the number of active candidates from the largest active candidate to the target. For a target of 34, the first armature is 1 because 33, the first active candidate, is one active candidate away from the target 34 and the second armature is 3 because 48 is three active candidates away from the target 34.

For very large numbers, the first and second armatures may also be very large. Instead of transmitting or storing these numbers, it is possible to simply record the SSR record for each armature. The value of the first armature is “1.” The SMB and SMOB of the value “1” are “1” and “1”, respectively. The value of the second armature is “3”. The SMB and SMOB of the value “3” are “2” and “2”, respectively. The SSR record of the first armature may be expressed as “(1,1)” and the SSR record of the second armature may be expressed as “(2,2)”.

Using the SSR records of the armatures, the series of active candidates may be significantly reduced by computing a series of values from the set of active candidates having the same SSR records for the first and second armatures. For the example given above, the armatures and the corresponding SSR records are computed as shown in Table 2 below.

TABLE 2

| T | T | Armature | Armature 1 | Armature | Armature 2 |
|---|---|---|---|---|---|
| (Binary) | (Decimal) | 1 | SSR Record | 2 | SSR Record |
| 100001 | 33 | 0 | (0,0) | 4 | (3,1) |
| 100010 | 34 | 1 | (1,1) | 3 | (2,2) |
| 100100 | 36 | 2 | (2,1) | 2 | (2,1) |
| 101000 | 40 | 3 | (2,2) | 1 | (1,1) |
| 110000 | 48 | 4 | (3,1) | 0 | (0,0) |

A set of good candidates may be created from the set of active candidates by selecting those active candidates having the same armature SSR records as the target T (step 210). In this example, the target is the only active candidate that has the SSR records (1,1) and (2,2). Thus, the target T may be uniquely specified as a number having an SSR record of (6,2), having a first armature with an SSR record of (1,1), and having a second armature with an SSR record of (2,2).

For very large target values, the number of good candidates may still be very large. Some implementations may further reduce the information needed to differentiate the target by computing a differential pair for each good candidate in the series (step 212). A differential pair includes two numbers with the first number representing the number of active candidates between the good candidate and the previous good candidate in the series, and the second number representing the number of active candidates between the good candidate and the next good candidate in the series.

For example, the following series represents a series of active candidates with good candidates represented as “G” and the remaining active candidates represented as “A”: “AAGAAAGAGAAAAG”. In this series, the differential pair for the first good candidate (from left to right) is (0,3) because it has no previous good candidate and there are 3 active candidates between the first good candidate and the second good candidate. Traversing the series from left to right, the differential pair for each good candidate is as follows: (0,3); (3,1); (1,4); (4,0).

The main differential pair is determined by computing the differential pair of the target (step 214). For example, if the second good candidate were the target, then the main differential pair would be (3,1) because there are three active candidates between the target and the previous good candidate and one active candidate between the target and the next active candidate.

Using the main differential pair, the target may be identified from the set of good candidates by searching triplets of good candidates for a good candidates having the same differential pair as the target (step 216). As each triplet of good candidates is searched, a counter may be incremented whenever an exact match is found (step 218) (i.e., whenever a triplet having the same differential pair as the target is found).

The series of good candidates having the same difference pair as the target is generally small, so a counter may be effectively used to identify the target from within the series. The counter value representing the ordinal location of the target within the set of good candidates having the same differential pair as the target uniquely identifies the target (step 220).

Using relational differentiation encoding, a large target number may be represented using the following values: (1) the SSR record of the target; (2) the SSR record of the first armature of the target; (3) the SSR record of the second armature of the target; (4) the main difference pair; and (5) a counter representing the ordinal location of the target within the set defined by the above values. Thus, the target number 34 may be represented by the following: (1) the target's SSR record “(6,2)”; (2) the first armature's SSR record “(1,1)”(3) the second armature's SSR record “(2,2)”; (4) the main differential pair “(0,0)”; and (5) the counter “1”.

The ordinal location specified by the counter may be calculated from the first value within the set or from the last value within the set. In some implementations, an additional bit is used to specify whether the counter begins from the largest or smallest value of the set defined by the first four characteristics.

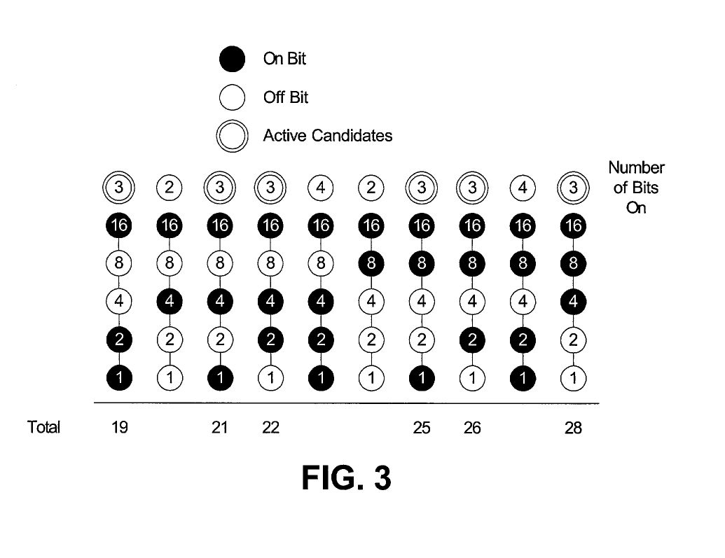

FIG. 3 shows an example of performing relational differentiation encoding of the target T=25. This target has a SMB or N equal to 5 (that is the target number is 5-bits and has a 1 in the senior most position). It also has an SMOB of 3 (the number of on bits) (SMOB=R=3). The one-to-many mapping discussed above establishes a combinatorial series of ^{N-1}C_{R-1} active candidates. FIG. 3 illustrates the bit patterns of each value between the smallest active candidate and the largest active candidates. Each value shown has a SMB of 5 and the SMOB of each value is listed above each bit pattern. The active candidates are those having a SMOB of 3. This expression equates to a combinatorial series consisting of the decimal numbers 19, 21, 22, 25, 26 and 28. The numbers 20, 23, 24, and 27 do not qualify as active candidates because their binary representation in 5-bits does not have the required SMOB=3.

As will be demonstrated, the system can encode and decode the number 25 for transmission and can distinguish it from among all of the other active candidates. The (^{N-1}C_{R-1}) expression creates a one-to-many result series of M candidates. The target location within the series can be identified through its relational “intimacy” to the other active candidates.

Having selected T=25, the next step is to determine the number of active candidates to the left and right of the target as illustrated in FIG. 3. The first of these numbers is Armature 1, while the second number is Armature 2. As shown in FIG. 3, there are three active candidates (19, 21, and 22) to the left of the target number 25 such that Armature 1 is equal to 3. There are two active candidates (26 and 28) to the right of the target, such that Armature 2 is equal to 2.

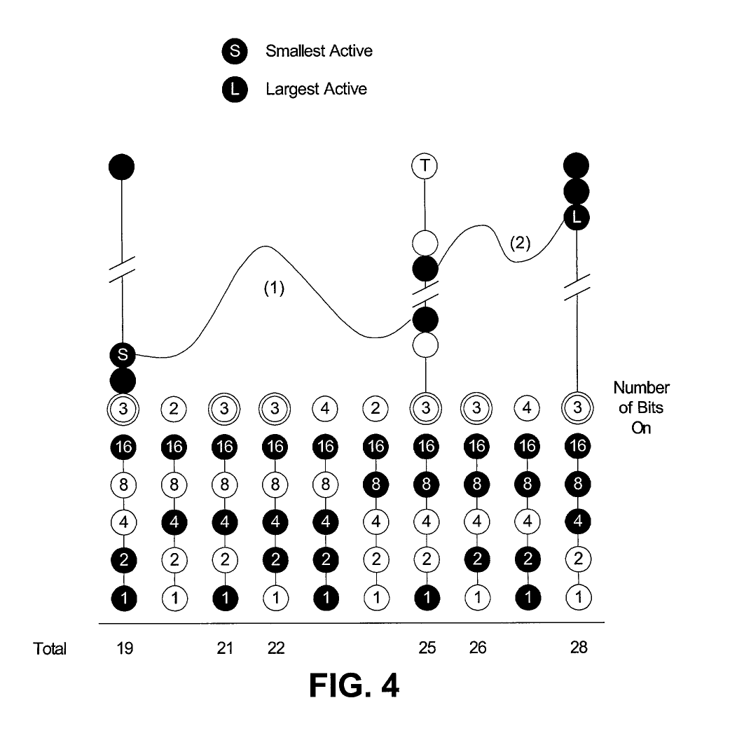

Referring to FIG. 4, relational differentiation encoding may be used to compute an efficient representation of the target within the series defined by the target's SSR record as described above. In this example, the target number 25 is encoded by creating a combinatorial ordinal series of active candidates defined by the SSR record of the target. FIG. 4 shows the use of two armatures to differentiate the target from the set of active candidates. The first armature specifies the position of the target T with respect to the small active candidate S and the second armature specifies the position of T with respect to the largest active candidate L.

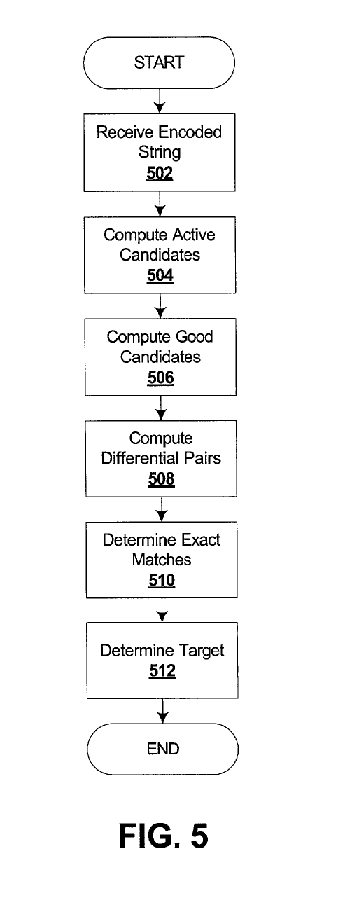

Referring to FIG. 5, the encoding process may be reversed to reconstitute the original bit string 102 from encoded bit stream 110 without loss. In the example discussed above with respect to Table 2, an encoded bit string of a target of 34 includes the following: (1) the target's SSR record “(6,2)”; (2) the first armature's SSR record “(1,1)”; (3) the second armature's SSR record “(2,2)”; (4) the main differential pair “(0,0)” and (5) the counter “1“.

The encoded bit string 110 includes a description of a series containing the target value. The decoding process begins by receiving the encoded bit string (step 502) and computing the active candidates in the series defined by the target's SSR record (step 504). The set of active candidates includes the target, which is fully differentiated by the remaining values in the encoded bit string. In this example, the target's SSR record is (6,2), which defines a set of active candidates including the following: 33, 34, 36, 40, and 48.

Using the first armature's SSR record and the second armature's SSR record, the good candidates may be determined from the set of active candidates by finding all active candidates having the same armature SSR records as the targets (step 506). In this example, only the value “34” has a first armature with an SSR record of (1,1) and a second armature with an SSR record of (2,2). Thus, the target value is 34. For this example, the decoding process would end here; however, for large values, further decoding, such as the use of the main differential pair and the counter, is typically required.

When necessary, the target may be further differentiated from other good candidates by calculating the differential pair for each of the good candidates (step 508). The counter can then be used to fully differentiate the target value from the set of good candidates having the same differential pair as the target (step 510). In this example, the differential pair for the single good candidate is (0,0) which matches the differential pair of the target. The counter specifies that the first matching good candidate is the target (step 512). Thus, the target value is 34.

The method described above may be implemented using digital computer technology. In some implementations, the method may be implemented using large scale integrated (LSI) circuits dedicated to the encoding and decoding process and optimized, from a hardware point of view, for this purpose. Thus, one or more digital circuits may be incorporated into modems, computers, or memory storage devices. Digital circuits may also be incorporated into “set top boxes” for use in transmission of movies and video information on cable television systems so that, for example, real time video, i.e., movies and the like, may be transmitted from a central source to a consumer's home on demand.

Accordingly, other implementations are within the scope of the following claims.

What is claimed is:

1. A computer-implemented method for encoding a target value for storage and/or transmission comprising:
constructing a set of values, the constructed set of values including the target value and the constructed set of values being characterized by a constructed set descriptor;
differentiating the target value from the constructed set of values by determining a differentiation descriptor; and
representing the target using the constructed set descriptor and the differentiation descriptor.

2. The computer-implemented method of claim 1 wherein constructing a set of values includes identifying a senior most bit of the target value.

3. The computer-implemented method of claim 1 wherein constructing a set of values includes computing a number of on bits of the target value.

4. The computer-implemented method of claim 1 wherein constructing a set of values includes computing a number of off bits of the target value.

5. The computer-implemented method of claim 1 wherein constructing a set of values includes creating a combinatorial ordered set.

6. The computer-implemented method of claim 5 wherein the combinatorial ordered set is defined by a senior most bit of the target value and a number of on bits of the target value.

7. The computer-implemented method of claim 5 wherein the combinatorial ordered set is defined by a senior most bit of the target value and a number of off bits of the target value.

8. The computer-implemented method of claim 6 wherein the constructed set descriptor includes the senior most bit of the target value and the number of on bits of the target value.

9. The computer-implemented method of claim 1 wherein differentiating the target value includes determining the position of the target value within the constructed set.

10. The computer-implemented method of claim 1 wherein differentiating the target value includes computing one or more armatures, each armature representing the position of the target value within the constructed set.

11. The computer-implemented method of claim 10 wherein:
the constructed set includes a first element and a last element; and
differentiating the target value includes:
computing a first armature representing the position of the target value relative to the first element of the constructed set; and
computing a second armature representing the position of the target value relative to the last element of the constructed set.

12. The computer-implemented method of claim 11 wherein differentiating the target value further includes constructing a set of good candidates from the constructed set of values.

13. The computer-implemented method of claim 12 wherein constructing the set of good candidates from the constructed set of values includes:
calculating one or more characteristics for each of the one or more armatures; and
representing the set of good candidates using the one or more characteristics for each of the one or more armatures.

14. The computer-implemented method of claim 13 wherein calculating one or more characteristics for each of the one or more armatures includes calculating a senior most bit and a number of on bits for each of the one or more armatures.

15. The computer-implemented method of claim 12 wherein differentiating the target value further includes constructing a set of exact matches from the set of good candidates.

16. The computer-implemented method of claim 15 wherein constructing a set of exact matches includes:
calculating a main difference pair for the target; and
characterizing the set of exact matches by the main difference pair.

17. The computer-implemented method of claim 16 wherein differentiating the target value further includes determining the ordinal position of the target within the set of exact matches.

18. The computer-implemented method of claim 17 wherein differentiation descriptor includes:
a senior most bit of the target;
a number of on bits of the target;
a senior most bit of each of the armatures;
a number of on bits of each of the armatures;
the main difference pair; and
the ordinal position of the target within the set of exact matches.

19. A computer program for performing relational differentiation encoding comprising:
a receiving code segment that receives data to be encoded using relational differentiation encoding, and creates a target value from the received data;
an encoding code segment operable to perform relational differential encoding on the received data, the encoding code segment including:
a series construction code segment operable to construct a set of active candidates including the target value;
a differentiation code segment operable to differentiate the target value from other values within the set of active candidates.

20. The computer program of claim 19 wherein the receiving code segment creates a target value from the received data by representing the received data as a single binary number.

21. The computer program of claim 19 wherein the receiving code segment creates a target value from the received data by representing a portion of the received data as a single binary number.

22. The computer program of claim 19 wherein the series construction code segment creates a combinatorial ordinal series.

23. The computer program of claim 22 wherein the combinatorial ordinal series is defined by a senior most bit of the target value and a number of on bits of the target value.

24. The computer program of claim 19 wherein the series construction code segment determines a senior most bit of the target value.

25. The computer program of claim 19 wherein the series construction code segment calculates a number of on or off bits of the target value.

26. The computer program of claim 19 wherein the differentiating code segment differentiates the target value from other values within the set of active candidates by determining the position of the target value within the set of active candidates.

27. The computer program of claim 26 wherein determining the position of the target within the set of active candidates includes computing one or more armatures, with each armature representing the position of the target value within the set of active candidates set.

28. The computer program of claim 26 wherein:
the set of active candidates includes a first element and a last element; and
differentiating the target value includes:
computing a first armature representing the position of the target value relative to the first element of the set of active candidates; and
computing a second armature representing the position of the target value relative to the last element of the set of active candidates.

29. The computer program of claim 28 wherein differentiating the target value further includes constructing a set of good candidates from the set of active candidates.

30. The computer program of claim 29 wherein constructing the set of good candidates from the set of active candidates includes:
calculating one or more characteristics for each of the one or more armatures; and
representing the set of good candidates using the one or more characteristics for each of the one or more armatures.

31. The computer program of claim 30 wherein calculating one or more characteristics for each of the one or more armatures includes determining the senior most bit and a number of on bits for each of the one or more armatures.

32. The computer program of claim 29 wherein differentiating the target value further includes constructing a set of exact matches from the set of good candidates.

33. The computer program of claim 32 wherein constructing a set of exact matches includes:
calculating a main difference pair for the target value; and
characterizing the set of exact matches by the main difference pair.

34. The computer program of claim 33 wherein differentiating the target value further includes determining the ordinal position of the target value within the set of exact matches.

35. The computer program of claim 34 wherein differentiating code segment creates a differentiation descriptor including:
a senior most bit of the target;
a number of on bits of the target;
a senior most bit of each of the armatures;
a number of on bits of each of the armatures;
the main difference pair; and
the ordinal position of the target within the set of exact matches.

36. A data encoding system comprising:
a data receiving module for receiving a target value; and
a data encoding module,
wherein the data encoding module is operable to encode data using a senior most bit of the target value and a number of on bits of the target value.

37. The data encoding system of claim 36 wherein the data encoding module is a hardware-implemented module.

38. The data encoding system of claim 36 wherein the data encoding module is a software-implemented module.

39. The data encoding system of claim 36 wherein the data encoding module includes:
a hardware-implemented module; and
a software-implemented module, the software-implemented module using the hardware-implemented module to increase the performance of the data encoding system.
